(19) United States
(12) Patent Application Publication
(10) Pub. No.: US 2008/0054244 A1
(43) Pub. Date: Mar. 6, 2008

(54) PHASE CHANGE MEMORY DEVICE AND METHOD OF FORMING THE SAME

(75) Inventors: Jin-Il Lee, Gyeonggi-Do (KR); Ji-Eun Lim, Gyeonggi-Do (KR); Hye-Young Park, Gyeonggi-Do (KR); Sung-Lae Cho, Gyeonggi-Do (KR); Eun-Ae Chung, Gyeonggi-Do (KR); Ki-Vin Im, Gyeonggi-Do (KR); Byoung-Jae Bae, Gyeonggi-Do (KR); Young-Lim Park, Gyeonggi-Do (KR)

Correspondence Address: MARGER JOHNSON & MCCOLLOM, P.C., 210 SW MORRISON STREET, SUITE 400, PORTLAND, OR, 97204, US

(73) Assignee: Samsung Electronics Co., Ltd., Gyeonggi-do (KR)

(21) Appl. No.: 11/697,230

(22) Filed: Apr. 5, 2007

(30) Foreign Application Priority Data
Aug. 8, 2006 (KR) 10-2006-0074490

(51) Int. Cl. H01L 29/02

(52) U.S. Cl. 257/3; 438/104; 438/761

(57) ABSTRACT

In one embodiment, a phase change memory device includes an insulation structure over a substrate. The insulation structure ahs an opening defined therethrough. A first layer pattern is formed on sidewalls and a bottom of the opening. A second layer pattern is formed on the first layer pattern and substantially fills the opening.

### CROSS REFERENCE TO RELATED APPLICATION

This application claims priority from Korean Patent Application No. 10-20060074490 filed on Aug. 8, 2006, in the Korean Intellectual Property Office, the disclosure of which is incorporated herein by reference in its entirety.

### BACKGROUND

1. Field of the Invention

Embodiments exemplarily described herein generally relate to semiconductor devices such as phase change random access memory (PRAM) devices and methods of forming the same.

2. Description of the Related Art

Phase change random access memory (PRAM) devices rely on phase change materials, such as chalcogenide, which are capable of stably transitioning between amorphous and crystalline phases. The differing resistance values exhibited by the two phases are used to distinguish logic values of the memory cells. That is, an amorphous state exhibits a relatively high resistance, and a crystalline state exhibits a relatively low resistance. Typically, a predetermined amount of current is applied to (or removed from) the phase change materials to induce a phase transition.

PRAM devices may be formed according to a process that includes forming a lower electrode on a substrate, forming an insulation layer over the lower electrode, etching the insulation layer to form an opening exposing the lower electrode, and depositing a phase change material into the opening. Openings formed in such conventional insulation layers tend to have relatively narrow widths or relatively large aspect ratios. As a result, it is often difficult to fill the opening with the phase change material without creating defects such as a void, and the resulting phase change structure is not dense or non-uniform.

Such a PRAM device containing the aforementioned defects is shown in FIG. 1, which shows a void within a GST (a typical phase change material made of germanium (Ge), antimony (Sb), and tellurium (Te)) layer overlying a tungsten plug. Due to the presence of these defects, it is difficult to induce a phase change within the phase change material. As a result, a circuit between the lower electrode and a subsequently formed upper electrode may remain open. The invention addresses these and other disadvantages of the conventional art.

### SUMMARY

One embodiment exemplarily described herein can be generally characterized as a phase change memory device that includes an insulation structure over a substrate having an opening defined therethrough; a first layer pattern formed on sidewalls and a bottom of the opening; and a second layer pattern on the first layer pattern and substantially filling the opening.

### BRIEF DESCRIPTION OF THE DRAWINGS

FIG. 1 is an electron micrograph of a PRAM device formed according to the conventional method;

FIG. 2 shows a cross-sectional view of an exemplary embodiment of a PRAM device;

FIGS. 3A and 3B are graphs showing resistance variations of phase change memory devices shown in FIG. 2, incorporating nucleation layers of different thicknesses, relative to a reset current;

FIGS. 4A to 4C show cross-sectional view of an exemplary embodiment of a method of forming the phase change memory device shown in FIG. 2;

FIG. 5 is a graph showing the thickness of nucleation layers relative to the number of cycles in ALD process;

FIG. 6 is a graph showing the thickness of a nucleation layer relative to the number of cycles in an ALD process;

FIG. 7 is a timing chart illustrating an exemplary embodiment of a method of forming the phase change material layer shown in FIG. 2;

FIG. 8 is a graph showing the composition of a phase change material layer as a function of the flow rate of hydrogen within a ligand decomposition gas;

FIG. 9 is a graph showing the composition of a phase change material layer as a function of the flow rate of argon within a ligand decomposition gas;

FIG. 10 is a timing chart illustrating another exemplary embodiment of a method of forming the phase change material layer shown in FIG. 2;

FIG. 11 is a graph showing the composition of a phase change material layer as a function of reaction chamber pressure;

FIG. 12A is an electron micrograph of one embodiment of a PRAM device formed according to processes as exemplarily described with respect to FIGS. 4A to 4C;

FIG. 12B is an electron micrograph of another embodiment of a PRAM device;

FIG. 13 is a graph showing the resistance variation of a phase change memory device formed using a titanium nitride nucleation layer relative to a reset current;

FIG. 14 is a graph showing the resistance variation of a phase change memory device formed using a transition metal oxide such as a titanium oxide nucleation layer, relative to a reset current according to an embodiment of the invention;

FIG. 15 is a graph comparing the distribution of resistivity values of a conventional phase change memory device with the distribution of resistivity values of a phase change memory device formed according to processes as exemplarily described with respect to FIGS. 4A to 4C;

FIG. 16 is a cross-sectional view illustrating another exemplary embodiment of a phase change memory device; and

FIGS. 17A and 17B are cross-sectional views illustrating an exemplary embodiment of a method of forming the phase change memory device shown in FIG. 16.

### DETAILED DESCRIPTION

Embodiments of the present invention will be described more fully hereinafter with reference to the accompanying drawings. These embodiments may, however, be realized in many different forms and should not be construed as limited to the example embodiments set forth herein. Rather, these exemplary embodiments are provided so that this disclosure will be thorough and complete, and will fully convey the scope of the present invention to those skilled in the art. In the drawings, the sizes and relative sizes of layers and regions may be exaggerated for clarity.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

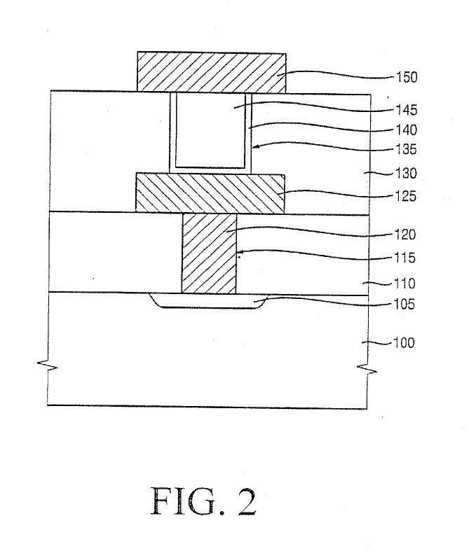

FIG. 2 shows a cross-sectional view of an exemplary embodiment of a PRAM device.

Referring to FIG. 2, a PRAM device includes an insulation layer 130 over a substrate 100 (e.g., a semiconductor substrate, a single crystalline metal oxide substrate, or the like), wherein the insulation layer 130 has an opening 135 defined therethrough. A first layer pattern 140 is located within the opening 135 and a second layer pattern 145 is located on the first layer pattern 140.

According to one aspect of the present invention, the first layer pattern 140 is conformally formed on sidewalls and a bottom of the opening 135. As illustrated, the second layer pattern 145 substantially fills the opening 135 and has an upper or outer surface that is substantially coplanar with a top surface of the insulation layer 130. Thus, the second layer pattern 145 may have a three-dimensional structure such as a contact structure.

According to some embodiments, the first layer pattern 140 may also be referred to as a nucleation layer pattern. Further, the second layer pattern 145 may include phase change material and may, therefore, be referred to as a phase change material layer pattern.

In one embodiment, the insulation layer 130 serves as a mold for forming the nucleation layer pattern 140 and the phase change material layer pattern 145. In another embodiment, the insulation layer 130 may electrically insulate the upper electrode 150 from underlying conductive structures. In one embodiment, the insulation layer 130 may include one or more materials such as an oxide (e.g., silicon oxide), a nitride (e.g., silicon nitride), and/or an oxynitride (e.g., silicon oxynitride, titanium oxynitride). In one embodiment, the silicon oxide of the insulation layer 130 may be provided as a USG, SOG, FOX, BPSG, PSG, TEOS, PE-TEOS, HDP-CVD oxide material, or the like, or combinations thereof.

In one aspect, the opening 135 may have an aspect ratio (i.e., a ratio of height:width) from about 5 to about 8 (.e.g., about 6). For example, the opening 135 may have a width of about 50 nm. Also, the opening 135 may have a height of about 3000 Å.

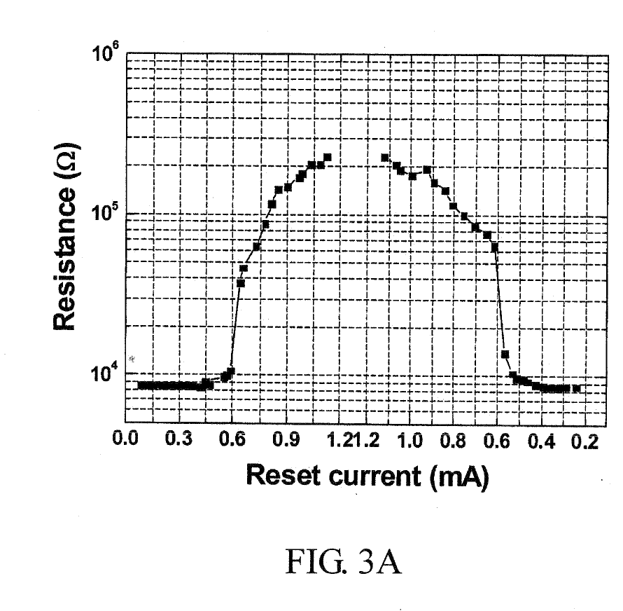

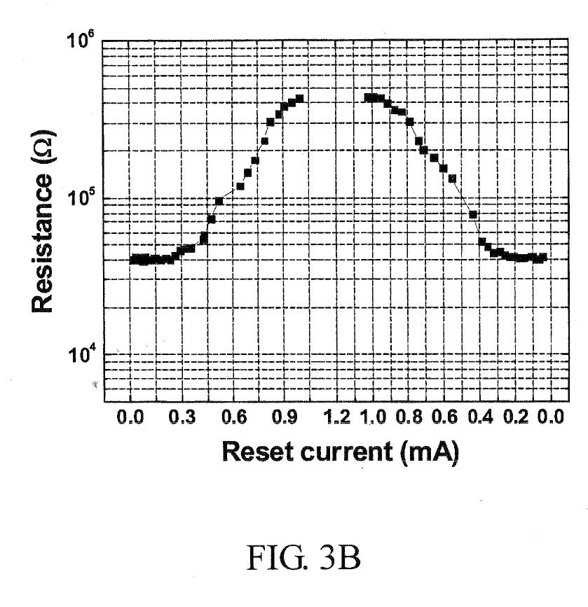

In another aspect, the nucleation layer pattern 140 may include a material such as a transition metal oxide such as titanium oxide (TiOₓ), niobium oxide (NbOₓ), zirconium oxide (ZrOₓ), or the like, or combinations thereof. In another embodiment the nucleation layer pattern 140 may include a material having a high electrical resistance (e.g., an electrical resistance of at least about 1×10⁶Ω to about 1×10⁹Ω). In another embodiment, the nucleation layer pattern 140 may be substantially amorphous. In yet another embodiment, the nucleation layer pattern 140 may have substantially uniform thickness. In one embodiment, the nucleation layer pattern 140 may have a thickness of about 10 Å to about 30 Å. More preferably, the nucleation layer pattern 140 has a thickness of about 10 Å for reasons described below with respect to FIGS. 3A and 3B.

FIGS. 3A and 3B are graphs showing resistance variations of phase change memory devices shown in FIG. 2, incorporating nucleation layer patterns 140 of different thicknesses, relative to a reset current.

Specifically, FIG. 3A shows the resistance variation of a phase change memory device incorporating a titanium oxide (TiOₓ) nucleation layer pattern having a thickness of about 10 Å, relative to a reset current. On the other hand, FIG. 3B shows the resistance variation of a phase change memory device incorporating a TiOₓ nucleation layer pattern having a thickness of 20 Å, relative to a reset current. As shown in FIGS. 3A and 3B, when the thickness of the nucleation layer pattern increases, the difference in resistance values between the amorphous and crystalline states decreases. That is, the sensing margin of the phase change memory device becomes degraded as the thickness of the nucleation layer pattern increases.

Also, when the titanium oxide layer is formed having a thickness of, for example, about 10 Å to about 20 Å, the titanium oxide layer having a relatively uniform thickness can be conformally formed within the opening 135.

In one aspect, the phase change material layer pattern 145 may include a material such as a chalcogenide (e.g., GST, AgInSbTe InSe, SbSe, SbTe, InSbSe, InSbTe, GeSbSe, GeSbTeSe, AgInSbSeTe, or the like, or combinations thereof). In another aspect, the phase change material layer pattern 145 may have a crystal structure that includes both face-centered-cubic (FCC) and hexagonal-close-packed (HCP) crystal structures.

Still Referring to FIG. 2, the phase change memory device may further include an upper electrode 150 located on the nucleation layer pattern 140 and the phase change material layer pattern 145 (e.g., contacting the nucleation layer pattern 140 and the phase change material layer pattern 145). In another embodiment, the upper electrode 150 may also be located on the insulation layer 130. The upper electrode 150 may include a material such as a metal (e.g., W, Al, Cu, Ta, Ti, Mo, or the like, or combinations thereof), a metal nitride (e.g., WNₓ, AlNₓ, TiNₓ, TaNₓ, MoNₓ, NbNₓ, TiSiNₓ, TiAlNₓ, TiBNₓ, ZrSiNₓ, WSiNₓ, WBNₓ, ZrAlNₓ, MoSiNₓ, MoAlNₓ, TaSiNₓ, TaAlNₓ, or the like or combinations thereof), or polysilicon doped with impurities, or the like, or combinations thereof.

As shown in FIG. 2, a component 125 may be provided such that it is exposed by the opening 135. In the illustrated embodiment, the component 125 may be located under the insulation layer 130 such that opening 135 exposes the component 125 beneath the insulation layer 130. In one embodiment, the nucleation layer pattern 140 may be located on the exposed portion of component 125 and on the sidewall of the opening 135.

The component 125 may be provided as a lower electrode of the phase change memory device described above. When provided as a lower electrode, the component 125 may include a material such as a metal (e.g., W, Al, Cu, Ta, Ti, Mo, or the like, or combinations thereof), a metal nitride (e.g., WNₓ, AlNₓ, TiNₓ,TaNₓ, MoNₓ,NbNₓ, TiSiNₓ, TiAlNₓ, TiBnₓ, ZrSiNₓ, WSiNₓ, WBNₓ, ZrAlNₓ, MoSiNₓ, MoAlNₓ, TaSiNₓ, TaAlNₓ, or the like, or combinations thereof), a metal silicide such as CoSi₂ or polysilicon doped with impurities, or the like or combinations thereof.

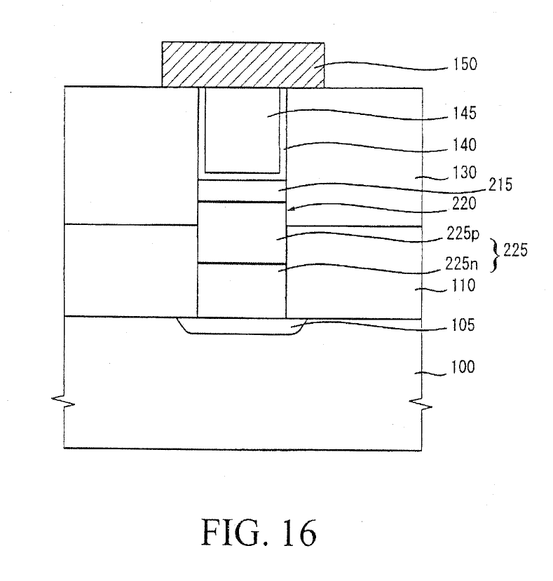

As shown in FIG. 2 are a lower structure 150 on the substrate, an interlayer insulating layer 110 over the lower structure 105, a contact hole 115 extending through the interlayer insulating layer 110 and a pad (or a plug) 120 within the contact hole 115. The component 125 and the pad 120 may be replaced by another component such as a diode and a lower electrode, which are sequentially stacked, as will be explained with respect to FIG. 16.

The lower structure 105 may be provided as, for example, an impurity region, a contact region, a conductive layer pattern, an insulation layer pattern, a pad, a spacer, a gate structure and/or a transistor.

The interlayer insulating layer 110 may be provided on the substrate 100 to cover the lower structure 105. The interlayer insulating layer 110 may include one or more materials such as an oxide (e.g., silicon oxide), a nitride (e.g., silicon nitride), and/or an oxynitride (e.g., silicon oxynitride, titanium oxynitride). In one embodiment, the silicon oxide of the interlayer insulating layer 110 may be provided as a USG, SOG, FOX, BPSG, PSG, TEOS, PE-TEOS, HDP-CVD oxide material, or the like, or combinations thereof.

The pad 120 may be located within the contact hole 115 formed through the interlayer insulating layer 110 and electrically connect the lower structure 105 with the component 125. In one embodiment, the pad 120 may include a material such as a metal (e.g., W, Al, Cu, Ta, Ti, Mo, or the like, or combinations thereof), a metal nitride (e.g., WNₓ, AlNₓ, TiNₓ, TaNₓ, MoNₓ, NbNₓ, TiSiNₓ, TiAlNₓ, TiBNₓ, ZrSiNₓ, WSiNₓ, WBNₓ, ZrAlNₓ, MoSiNₓ, MoAlNₓ, TaSiNₓ, TaAlNₓ, or the like, or combinations thereof), or polysilicon doped with impurities, or the like, or combinations thereof.

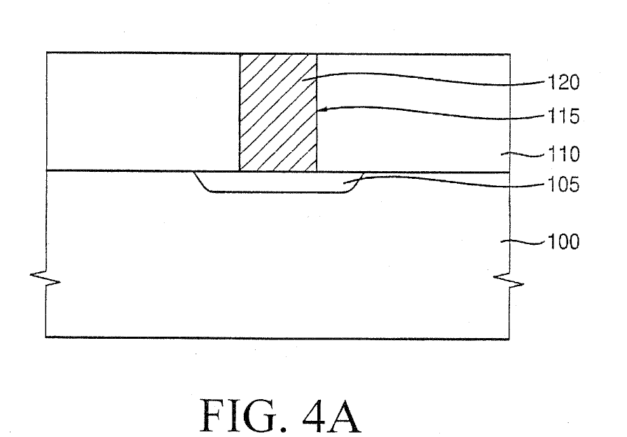

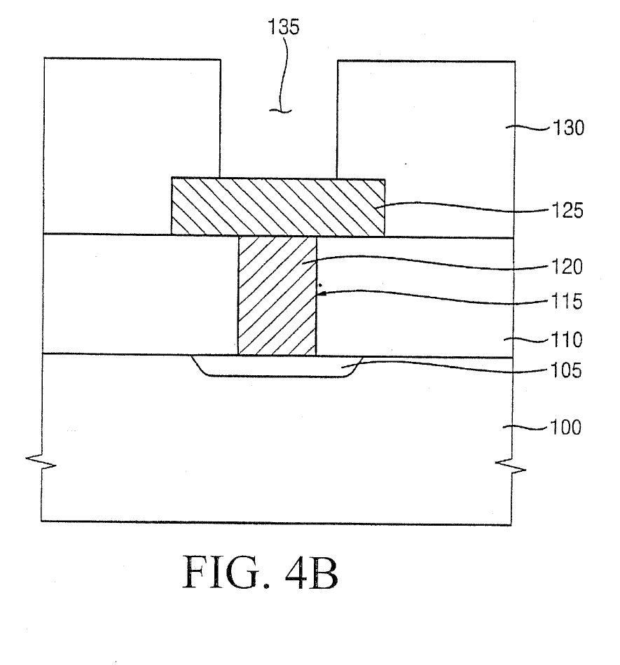

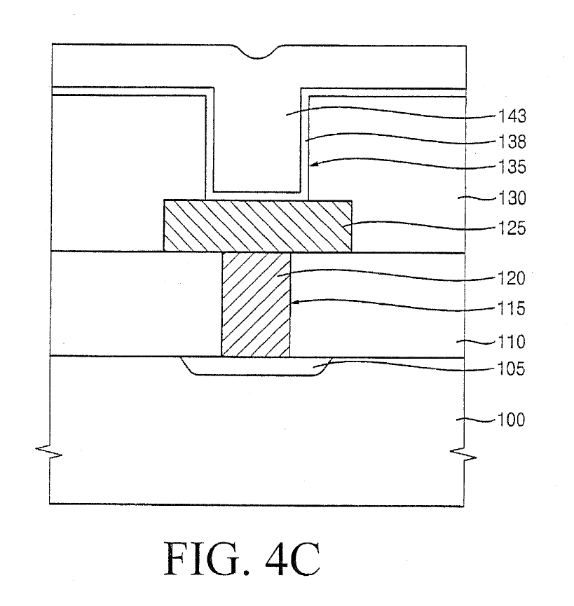

Having described the phase change memory device above with respect to FIG. 2, an exemplary manner of forming the device shown in FIG. 2 will now be described with respect to FIGS. 4A-4C.

Referring to FIG. 4A, a lower structure 105 may be formed on a substrate 100 and then an interlayer insulating layer 110 may be formed on the substrate 100 to cover the lower structure 105. The interlayer insulating layer 110 may be formed according to any suitable process (e.g., a CVD process, an LPCVD process, a PECVD process, an HDP-CVD process, or the like, or combinations thereof). In one embodiment, the interlayer insulating layer 110 may be subjected to a process such a CMP process and/or an etch back process (planarized) to provide the interlayer insulating layer 110 with an upper surface that is substantially planar.

A contact hole 115 may then be formed through the interlayer insulating layer 110 according to a photolithography process and an etching process such as an anisotropic etching process. In one embodiment, the contact hole 115 exposes the lower structure 105.

Next, a conductive layer (e.g., a first conductive layer) may be formed on the interlayer insulating layer 110 to fill the contact hole 115. The first conductive layer may include a material such as doped polysilicon, metal, metal nitride, or the like or combinations thereof. In one embodiment, the first conductive layer may be formed according to a sputtering process, a chemical vapor deposition (CVD) process, a low-pressure CVD (LPCVD) process, an atomic layer deposition (ALD) process, an E-beam evaporation process, a pulsed laser deposition (PLD) process, or the like, or combinations thereof. After formation, the first conductive layer may be partially removed (or planarized) (e.g., according to a CMP process and/or an etch back process) until the interlayer insulating layer 110 is exposed, thereby forming the pad 120 within the contact hole 115.

Referring to FIG. 4B, another conductive layer (e.g., a second conductive layer) may be formed on the pad 120 and on the interlayer insulating layer 110. The second conductive layer may include a material such as doped polysilicon, metal, metal nitride, or the like or combinations thereof. In one embodiment, the second conductive layer may be formed according to a sputtering process, a CVD process, an LPCVD process, an ALD process, an E-beam evaporation process, a PLD process, or the like, or combinations thereof. After formation, the second conductive layer may be patterned to form the component 125 (herein provided as a lower electrode) on the pad 120 and on the interlayer insulating layer 110.

Next, the insulation layer 130 may be formed on the interlayer insulating layer 110 to cover the component 125. The insulation layer 130 may be formed according to any suitable process (e.g., a CVD process, an LPCVD process, a PECVD process, an HDP-CVD process, or the like, or combinations thereof). In one embodiment, the insulation layer 130 may be subjected to a process such a CMP process and/or an etch back process to provide the insulation layer 130 with an upper surface that is substantially planar. According to some embodiments, the thickness of the insulation layer 130 may affect the dimensions of a subsequently formed change material layer pattern 145.

An opening 135 may then be formed through the insulation layer 130 according to, for example, a photolithography process and etching process such as an anisotropic etching process. In one embodiment, the photolithography process may be used to expose the component 125. According to some embodiments, the dimensions of the opening 135 (e.g., height and width) may affect the dimensions of a subsequently formed phase change material layer pattern 145. As discussed above, the opening 135 may have an aspect ratio from about 5 to about 8 (e.g., about 6). However, the present invention is not limited to this particular aspect ratio and can be applied to other phase change memory devices within the spirit and scope of the present invention. For example, the opening 135 can be filled with a phase change material without a void or very small void, if any, so as not to prevent the device from properly operating.

Referring to FIG. 4C, a nucleation layer 138 may be formed on the resulting structure, for example, within the opening 135 (e.g., on the exposed component 125 and sidewalls of the opening 135) and on the top surface of the insulation layer 130 using a process described below. Subsequently, a phase change material layer 143 may be formed on the resulting structure, e.g., substantially the entire area of the nucleation layer 138 to fill the opening 135 using a process described further below.

According to some embodiments, the nucleation layer 138 allows the phase change material layer 143 to have substantially uniform grain size and good step coverage. Thus, the phase change material layer 143 may substantially fill the opening 135 even though width of the opening 135 may be small or the aspect ratio of the opening 135 may be large.

Referring back to FIG. 2, the phase change material layer 143 and the nucleation layer 138 are then patterned or planarized to form a structure as shown. In one embodiment, the patterning may be performed by removing portions of phase change material layer 143 and nucleation layer 138 (e.g., by a CMP process and/or an etch back process) until the insulation layer 130 is exposed, thereby forming the aforementioned nucleation layer pattern 140 and phase change material layer pattern 145. As illustrated, the nucleation layer pattern 140 may be formed on the component 125 and on the sidewall of the opening 135, and the phase change material layer pattern 145 is located on the nucleation layer 140 to substantially fill the opening 135.

In another embodiment, only the phase change material layer 143 may be planarized or patterned (e.g., by a CMP process and/or an etch back process) until the nucleation layer 138 is exposed. In such an embodiment, the nucleation layer 138 may remain on the top surface of the insulation 130 while the phase change material layer pattern 145 substantially fills the opening 135.

Referring still to FIG. 2, yet another conductive layer (i.e., a third conductive layer) may be formed on the phase change material layer pattern 145, the nucleation layer pattern 140 and the insulation layer 130. The third conductive layer may include a material such as doped polysilicon, metal, metal nitride, or the like or combinations thereof. In one embodiment, the third conductive layer may be formed according to a sputtering process, a CVD process, an LPCVD process, an ALD process, an E-beam evaporation process, a PLD process, or the like, or combinations thereof. After formation, the third conductive layer may be patterned to form an upper electrode 150 on the phase change material layer pattern 145, the nucleation layer pattern 140 and the upper insulation 130.

Having generally described the process of forming the phase change memory device shown in FIG. 2, exemplary processes of forming the nucleation layer 138 and phase change material layer 143 will now be described in greater detail.

In one embodiment, the nucleation layer 138 may be formed according to a process such as ALD. In such an embodiment, the nucleation layer 138 may be formed at a temperature between about 300 and 350° C. and at a pressure between about 0.4 and 0.8 Torr. For example, in one embodiment where the nucleation layer 138 includes TiOₓ material, the nucleation layer 138 may be formed by loading the substrate 110 into a reaction chamber and providing a reactive precursor (e.g., including TiCl₄ or titanium tetrakis-isopropoxide (TTIP)) onto the substrate 100 to form a chemisorption layer on the component 125, the sidewall of the opening 135 and on the insulation layer 130. The reaction chamber may then be purged and, subsequently, an oxidizing agent including ozone may be provided on the chemisorption layer to thereby form the nucleation layer of TiOₓ on the component 125, the sidewall of the opening 135 and on the insulation layer 130. Formed according to the above-described process, the nucleation layer 138 formed of TiOₓ may have a high electrical resistance, good step coverage and substantially uniform thickness.

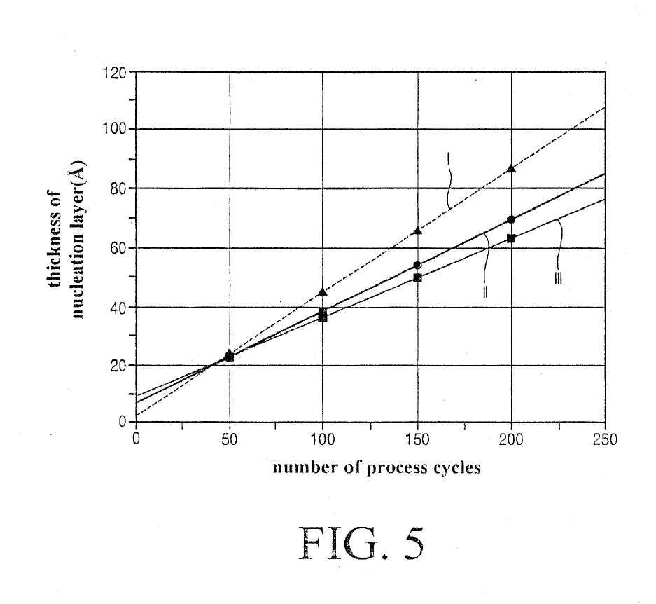

FIG. 5 is a graph showing the thickness of nucleation layers relative to the number of cycles in an ALD process.

In FIG. 5, the symbol “▴” indicates the thickness variation of a first nucleation layer (I) formed by sequentially providing a reactive precursor for about 4.0 seconds, an oxidizing agent for about 4.0 seconds and then purging the reaction chamber for about 10 seconds. The symbol “” represents the thickness variation of a second nucleation layer (II) formed by sequentially providing a reactive precursor for about 2.0 seconds, providing an oxidizing agent for about 2.0 seconds and then purging the reaction chamber for about 10 seconds. The symbol “▪” denotes the thickness variation of a third nucleation layer (III) formed by sequentially providing a reactive precursor for about 1.0 second, providing an oxidizing agent for about 1.0 seconds and then purging the reaction chamber for about 10 seconds. Each of first to the third nucleation layers (I, II and III) were formed using TTIP as the reactive precursor and ozone as the oxidizing agent at a temperature of about 320° C. and a pressure of about 0.61 Torr.

As shown in FIG. 5, the relationship between the thickness variation and the number of the cycle is represented as Y=0.42X+2.2 Å when the thickness of the first nucleation layer (I) is Y and the number of the cycles of the ALD process is X. Additionally, the relationship between the thickness variation and the number of the cycle is represented as Y=0.31X+6.9 Å when the thickness of the second nucleation layer (II) is Y and the number of the cycles of the ALD process is X. Furthermore, the relationship between the thickness variation and the number of the cycle is represented as Y=0.27X+9.0 Å when the thickness of the third nucleation layer (III) is Y and the number of the cycles of the ALD process is X.

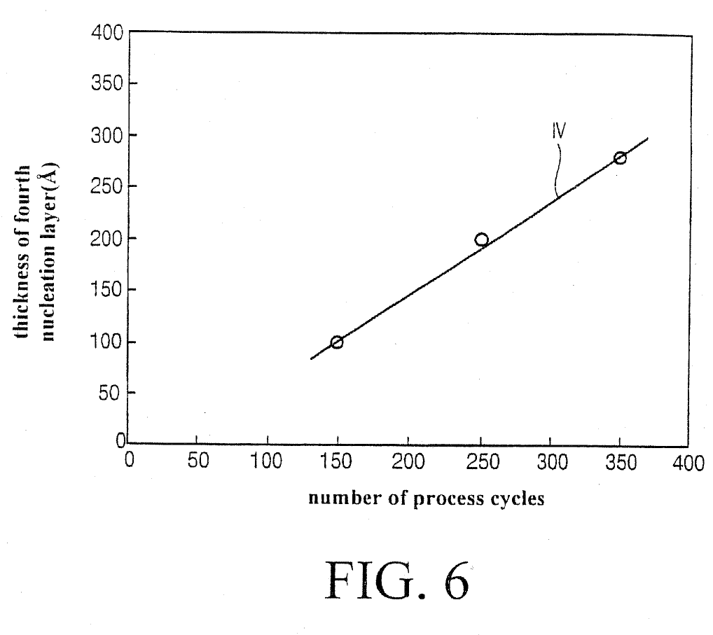

FIG. 6 is a graph showing the thickness of a nucleation layer relative to the number of cycles in an ALD process.

In FIG. 6, the fourth nucleation layer is obtained by sequentially providing a reactive precursor for about 0.5 seconds, purging the reaction chamber for about 0.5 seconds, providing an oxidizing agent for about 1.0 seconds and purging the reaction chamber for about 0.5 seconds.

As shown in FIG. 6, the relationship between the thickness variation and the number of the cycle is represented as Y=0.9X−31.6 Å when the thickness of the fourth nucleation layer (IV) is Y and the number of the cycles of the ALD process is X.

With the above-mentioned relationships between the thickness variations of the nucleation layers and the number of the cycles of the ALD process, the thickness of the nucleation layer 138 may be properly adjusted by controlling the number of cycles in the ALD process while ensuring the uniformity of the nucleation layer.

In one embodiment, the phase change material layer 143 may be formed according to a process such as CVD, ALD, CVD, metal-organic CVD (MOCVD), physical vapor deposition (PVD), or the like. In one embodiment, the phase change material layer 143 may be formed at a temperature between about 250 to about 500° C. and at a pressure between about 0.000001 Torr and about 10 Torr. In one embodiment, the reaction chamber pressure may be greater than 2 Torr and less than or substantially equal to 3 Torr. In one embodiment, the phase change material layer 143 may comprise GST material. In another embodiment, the GST material may consist of about 20% Ge.

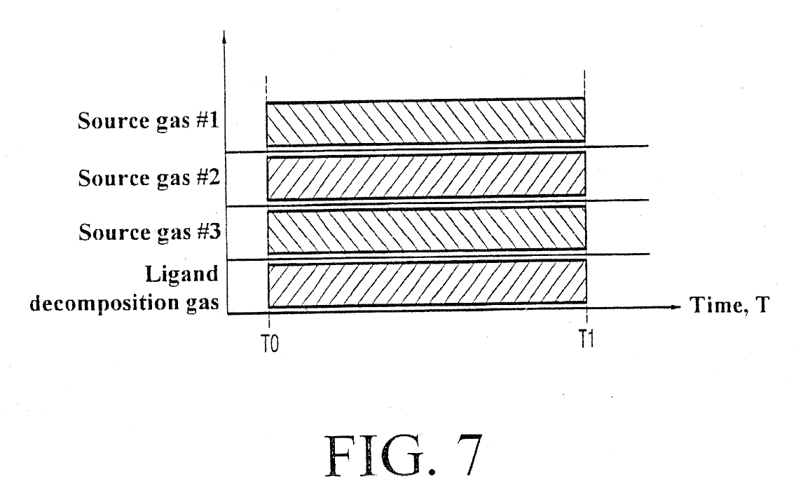

FIG. 7 is a timing chart illustrating an exemplary embodiment of a method of forming the phase change material layer shown in FIG. 2.

Referring to FIG. 7, in one embodiment where the phase change material layer 143 includes GST material, the phase change material layer 143 may be formed by loading the substrate 100 having the nucleation layer 138 into a reaction chamber and simultaneously providing a first source gas including Ge, a second source gas including Sb, a third source gas including Te and a ligand decomposition gas onto the substrate 100 having the nucleation layer 138. Accordingly, a phase change material layer 143 having a composition of Ge_{X}Sb_{Y}Te_{Z} (wherein X+Y+Z−1) may be formed on the nucleation layer 138.

The first source gas may include Ge(i-Pr)(NEtMe)₃ or Ge(CH₂CHCH₂)₄ and the second source gas may include Sb(iPr)₃ or Sb(CH(CH₃)₂)₃. Additionally, the third source gas may include Te(tBu)₂ or Te(CH(CH₃)₃)₂ and the ligand decomposition gas may include Ar, H₂ or NH₃.

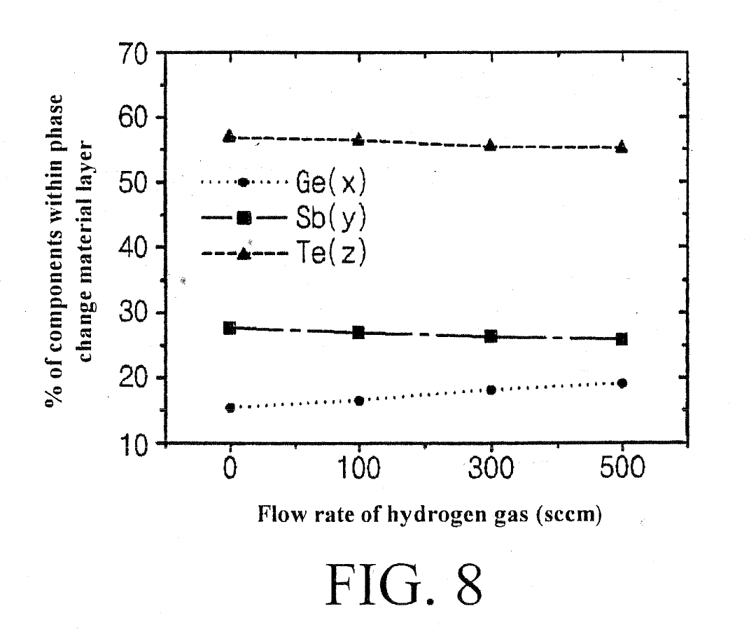

FIG. 8 is a graph showing the composition of a phase change material layer as a function of the flow rate of hydrogen within a ligand decomposition gas.

Referring to FIG. 8, the content of Ge (x) in the phase change material layer 143 increases from about 16% to about 20% whereas the content of Sb (y) in the phase change material layer is reduced from about 27% to about 25% when the flow rate of the hydrogen gas is increased from about 0 sccm to about 500 sccm. Additionally, the content of Te (z) in the phase change material layer 143 decreases from about 57% to about 55% when the flow rate of the hydrogen gas is increased from about 0 sccm to about 500 sccm. Accordingly, the percentage of Ge, Sb and Te within the phase change material layer 143 may be controlled by adjusting the flow rate of the hydrogen component of the ligand decomposition gas.

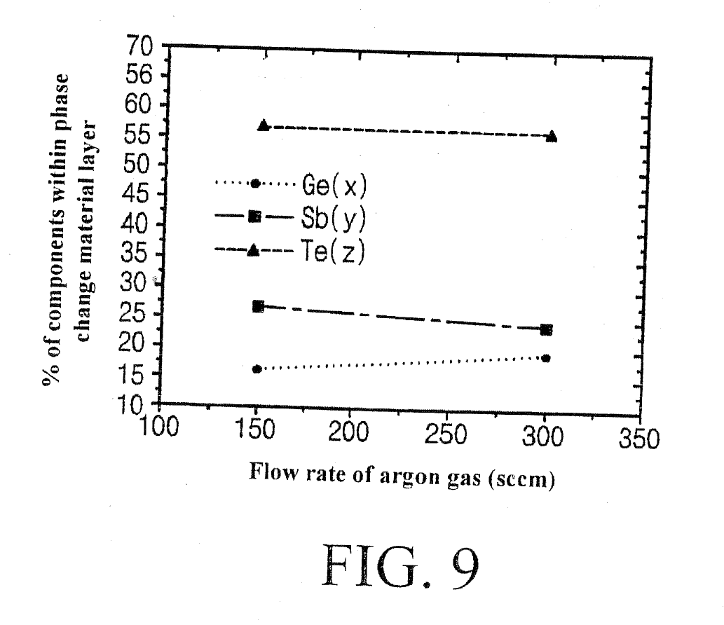

FIG. 9 is a graph showing the composition of a phase change material layer as a function of the flow rate of argon within a ligand decomposition gas.

Referring to FIG. 9, the content of Ge (x) in the phase change material layer 143 increases from about 16% to about 19% whereas the content of Sb (y) in the phase change material layer 143 decreases from about 27% to about 24% when the flow rate of argon gas is increased from about 150 sccm to about 300 sccm. However, the content of Te (z) in the phase change material layer 143 remains substantially the same (i.e., about 57%). Accordingly, the percentage of Ge and Sb may be controlled by adjusting the flow rate of the argon component of the ligand decomposition gas.

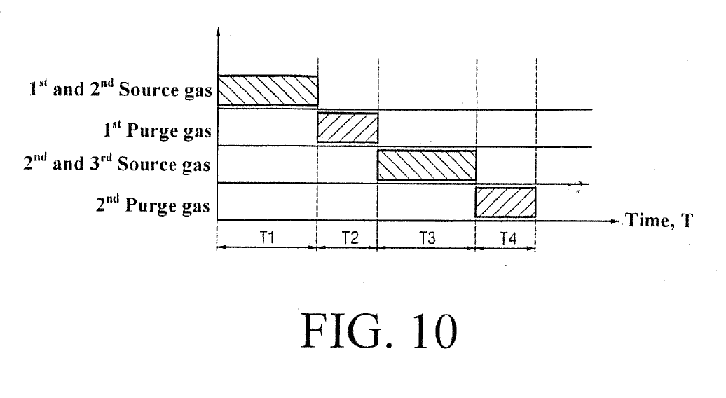

FIG. 10 is a timing chart illustrating another exemplary embodiment of a method of forming the phase change material layer shown in FIG. 2.

Referring to FIG. 10, in one embodiment where the phase change material layer 143 includes GST material, the phase change material layer 143 may be formed by loading the substrate 100 having the nucleation layer 138 into a reaction chamber and providing a first source gas including Ge and a second source gas including Te onto the substrate 100 for a first time period T1, thereby forming a composite layer of Ge—Te on the nucleation layer 138. Subsequently, the reaction chamber may be purged for a second time period T2 using a first purge gas (e.g., Ar and/or hydrogen). Next, the second source gas including Te and a third source gas including Sb may be provided onto the composite layer of Ge—Te for a third time period T3, thereby forming the phase change material layer 143 on the nucleation layer 138. Finally, the reaction chamber may be purged for a fourth time period T4 using a second purge gas (e.g., Ar and/or hydrogen).

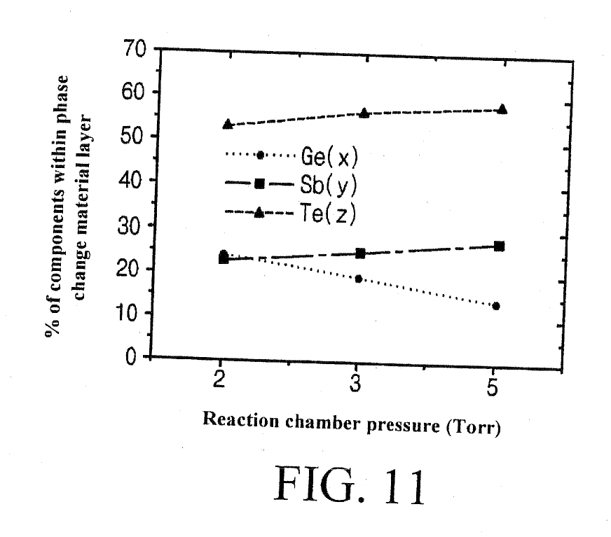

FIG. 11 is a graph showing the composition of a phase change material layer as a function of reaction chamber pressure.

Referring to FIG. 11, the content of Ge (x) in the phase change material layer is reduced from about 23% to about 14% whereas the content of Sb (y) in the phase change material layer is augmented from about 23% to about 28% as the pressure of the reaction chamber varies from about 2 Torr to about 4 Torr. Further, the content of Te (z) in the phase change material layer is increased from about 54% to about 58%. Accordingly, the contents of Ge, Sb and Te may be controlled by adjusting the pressure of the reaction chamber.

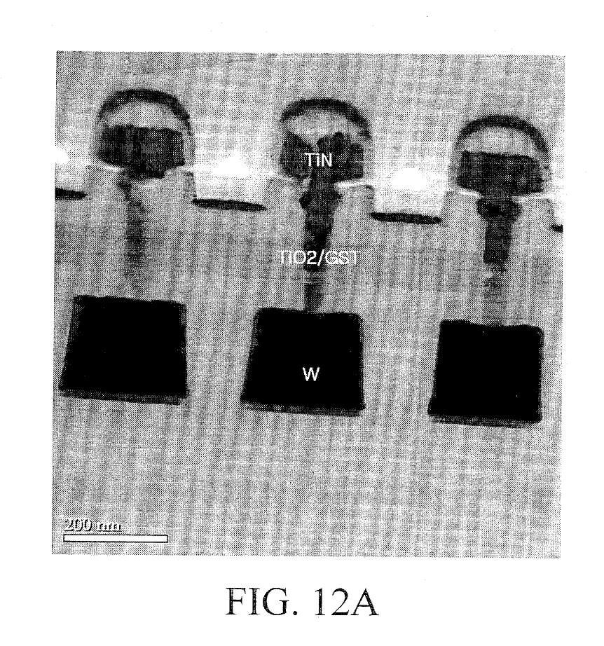

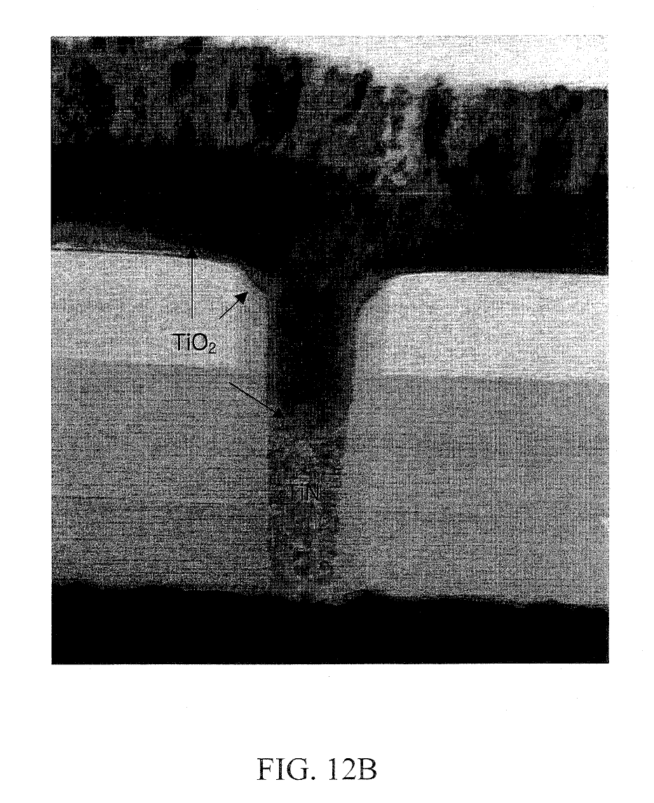

FIG. 12A is a TEM picture of one embodiment of a PRAM device formed according to processes as exemplarily described with respect to FIGS. 4A to 4C.

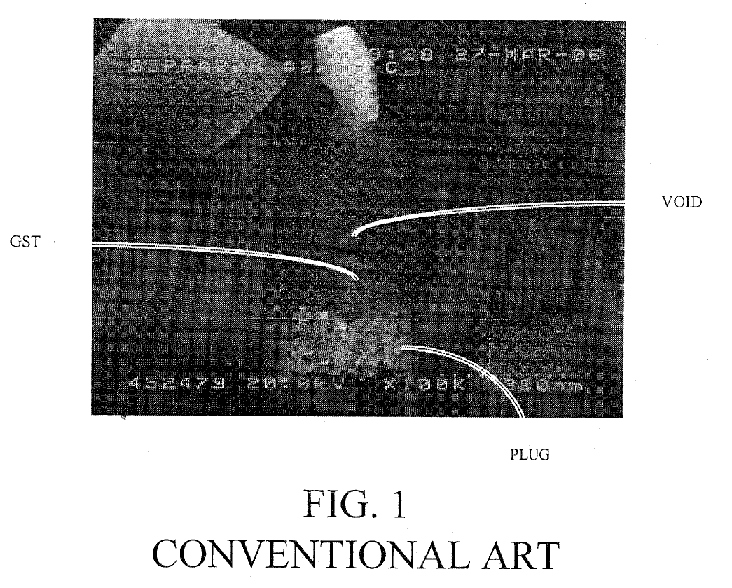

Referring to FIG. 12A, the phase change memory device includes a component (e.g., a lower electrode formed of W), a nucleation layer pattern formed of TiOₓ, a phase change material layer pattern formed of GST and an upper electrode formed of TiNₓ. As shown in FIG. 12A, the phase change material layer pattern fills an opening having a width of about 50 nm and a height of about 3,000 Å, without a void shown in FIG. 1, when the phase change material layer is grown from the nucleation layer.

FIG. 12B is a TEM picture of another embodiment of a PRAM device formed according to processes as described above.

Referring to FIG. 12B, the phase change memory device includes a component (e.g., a titanium nitride (TiN) plug formed within an opening defined through an insulation layer), a nucleation layer including titanium oxide, e.g., TiO₂ on the TiN plug and a phase change material layer on the nucleation layer. As shown in FIG. 12B, the nucleation layer is conformally formed over the sidewalls of the opening and on the TiN plug and has a substantially uniform thickness. Although Applicant does not wish to be held to a particular theory of operation, it is believed that with the nucleation layer pattern conformally formed within the opening, the phase change material layer can adequately fill the opening such that no voids or small voids that would not prevent the device from properly operating are present within the opening. Therefore, the defects such as a void that can read to an open circuit as discussed above can be avoided with embodiments of the present invention while obtaining the proper sensing margin of the phase change memory device.

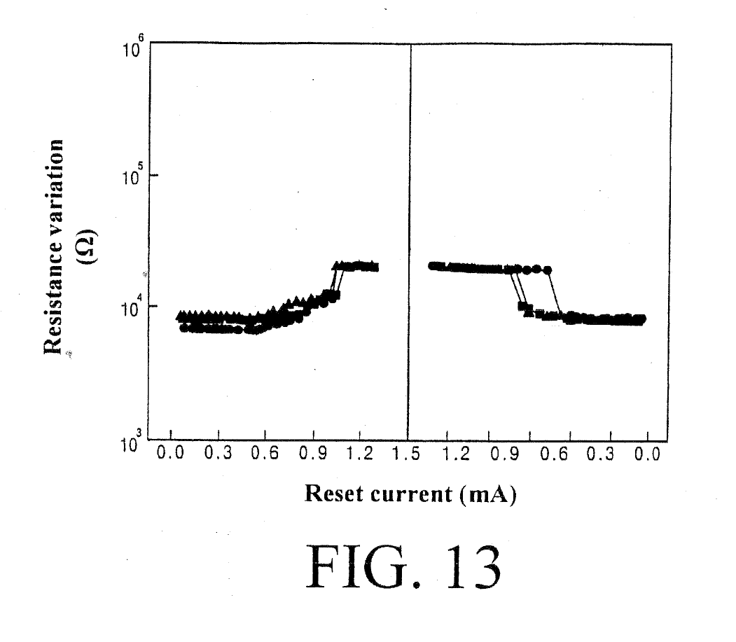

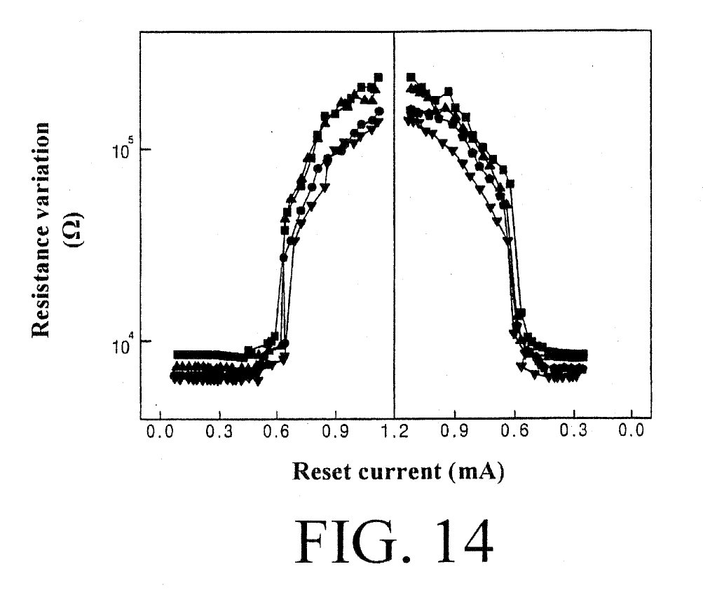

FIG. 13 is a graph showing the resistance variation of phase change memory devices formed using a titanium nitride nucleation layer relative to a reset current. FIG. 14 is a graph showing the resistance variation of phase change memory devices, formed using a transition metal oxide nucleation layer such as a titanium oxide nucleation layer, relative to a reset current. The phase change memory devices of FIG. 14 are formed according to an embodiment of the present invention, e.g., as shown in FIG. 2.

In particular, in FIG. 13, the phase transition of the phase change material layer may not properly occur. As a result, the resistance variation of the phase change material layer is very small (i.e., low sensing margin) when a reset current is applied from the lower electrode to the phase change material layer of the phase change memory device with the titanium nitride nucleation layer.

However, in FIG. 14, the phase transition of the phase change material layer may effectively occur. As a result, resistance variation of the phase change material layer is sufficiently large (a sufficient sensing margin) when a reset current is applied from an electrode to the phase change material layer formed using a nucleation layer including a transition metal oxide (e.g., a titanium oxide). It is believed that the nucleation layer comprised of other transition metal oxides such as ZrO₂ may also be suitable for forming the nucleation layer of the present invention.

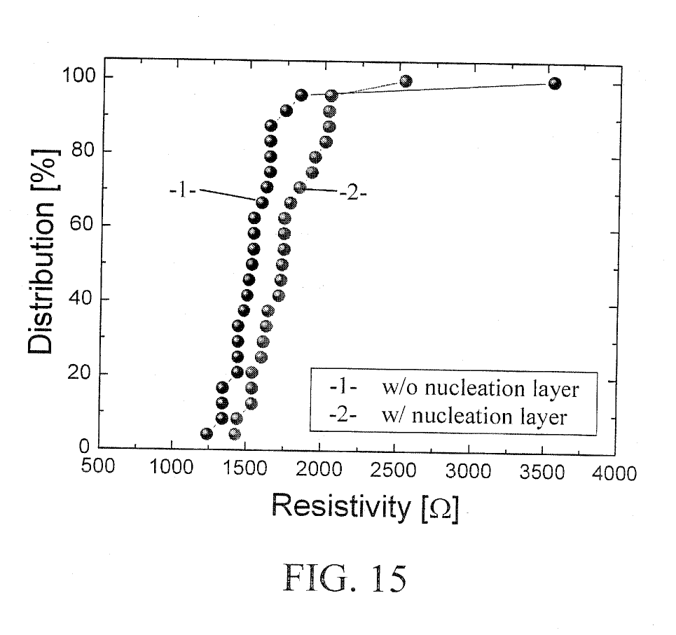

FIG. 15 is a graph comparing the distribution of resistivity values of a conventional phase change memory device with the distribution of resistivity values of a phase change memory device formed according to processes as exemplarily described with respect to FIGS. 4A to 4C.

Referring to FIG. 15, line “-1-” represents the distribution of series resistance values of a phase change memory device in which a phase change material layer pattern directly contacts a lower electrode while line “-2-” represents the distribution of series resistance values of one embodiment of a phase change memory device in which a titanium oxide nucleation layer pattern is interposed between the phase change material layer pattern and a lower electrode. As shown in FIG. 15, the distribution of series resistance values obtained when a nucleation layer pattern is interposed between the phase change material and an electrode is narrower than the distribution obtained when the phase change material directly contacts the electrode. Upon obtaining a relatively narrow distribution of resistivity values, the reliability of the phase change memory device can be increased.

FIG. 16 is a cross-sectional view illustrating another exemplary embodiment of a phase change memory device.

The phase change memory device shown in FIG. 16 may be similar to the device shown in FIG. 2 with some exceptions such as the presence of a diode 225. The interlayer insulating layer 110 may be formed on the substrate 100 to cover the lower structure 105, the insulation layer 130 may be formed on the interlayer insulating layer 110 and an opening 220 may be formed through the insulation layer 130 and the interlayer insulating layers 110 to thereby expose the lower structure 205. The diode 225 or other structure, provided as the aforementioned component, may partially fill the opening 220. In one embodiment, the diode 225 may include for, example, a semiconductor material such as a polysilicon material and formed according to a conventional process as understood by one skilled in the art. According to some embodiments, by employing the diode 225 as a switching device, sufficient current needed for each memory element to heat the phase change material can be supplied compared to a conventional metal oxide semiconductor (MOS) switch device even when the memory cell sizes continue to scale down.

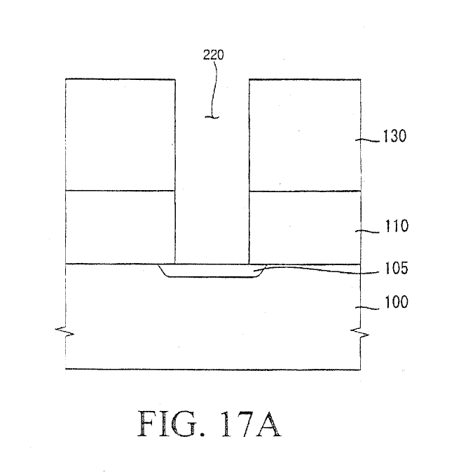

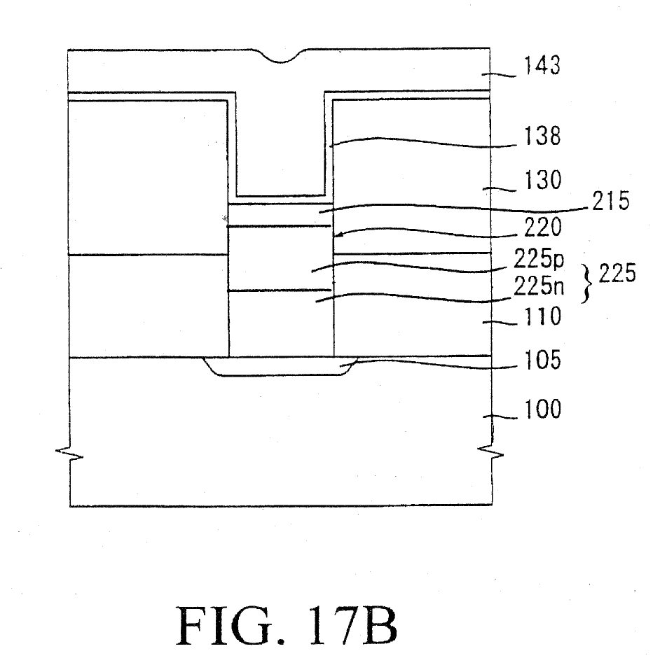

FIGS. 17A and 17B are cross-sectional views illustrating an exemplary embodiment of a method of forming the phase change memory device shown in FIG. 16.

Referring to FIGS. 16, 17A and 17B, the processes for forming the phase change memory device may be substantially the same as those described with reference to FIGS. 2 and 4A to 4C except for, for example, the formation of the opening 220, a lower electrode 215, and a diode 225. For example, as shown in FIG. 17A, the insulation layer 130 may be disposed over the interlayer insulating layer 110 and an opening 220 may be formed through both the insulation layer 130 and the interlayer insulating layer 110.

Referring to FIG. 17B, a diode 225 may be formed to partially fill the opening 220 using a process similar to one shown in Korean Application No. 2005-0053217 filed on Jun. 20, 2005 and having the same assignee as this application described above. This application is incorporated herein by reference in its entirety for all purposes. For example, an interlayer insulating layer 110 is formed on a semiconductor substrate 100. Then, an insulation layer 130 is formed over the interlayer insulating layer 110. Then, an opening 220 is formed through the insulation layer 130 and the interlayer insulating layer 110 using conventional techniques such as a photolithography and etching. Alternatively, a single layer of dielectric material (an insulation structure) is formed instead of the insulation layer 130 and the interlayer insulating layer 110, depending on applications before the opening 220 is formed therethrough.

Next, a semiconductor pattern is formed within the opening 220 (not illustrated) to form the diode 225. The semiconductor pattern may be formed by a selective epitaxial growth (SEG) technique using the lower structure 105 as a seed. Alternatively, the semiconductor pattern may be formed by chemical vapor deposition and sequent planarization processes, followed by a solid-phase epitaxial growth technique known to one skilled in the art.

Subsequently, the semiconductor pattern is recessed (not illustrated) by techniques such as an etch back process. Then, ion implantation processes are then performed to form an n-type impurity region 225n and a p-type impurity region 225p to form the diode 225.

Then, the lower electrode 215 formed of a conductive material such as a metal silicide (e.g., CoSi₂) may be formed over the diode 225. Alternatively, the lower electrode 215 may be formed using a method disclosed in Korean Application No. 2005-0053217, discussed above. In this case, an insulating spacer is formed overlying the diode 225 (having a cell diode contact) on sidewalls of the opening 220. Thereafter, a conductive material is filled within the spacer formed on sidewalls of the opening 220 to the lower electrode 215 and planarized. The lower electrode 215 is in electrical contact with the cell diode contact. Then, the nucleation and phase change material layers 138 and 143 may then be formed within the remaining part of the opening 220 similar to the process described with respect to FIG. 4C. Next, the phase change material layer 143 and the nucleation layer 138 are patterned (e.g., according to a CMP process and/or an etch back process) to form the nucleation layer pattern 140 and phase change material layer pattern 145 shown in FIG. 16.

Subsequently, an upper electrode 150 may be formed on the resulting structure, for example, in a manner as similarly described with respect to FIG. 2. Subsequently, metallization processes are performed to form interconnection lines as known in the art. One of ordinary skill in the art will realize that the invention may be practiced without the use of these specific details such as forming an isolation layer and so on.

As described above, the nucleation layer pattern facilitates filling of an opening having a small width or large aspect ratio without a void which is shown in FIG. 1 that can degrade a reliability of a phase change memory device or cause a device failure or a poor sensing margin. Moreover, the presence of the nucleation layer pattern allows the phase change material layer pattern to have substantially uniform grain sizes within the opening. Further, according to embodiments of the invention, it has been shown that the reliability or sensing margin of the phase change memory device can be significantly improved as in FIGS. 14-15.

The semiconductor devices made according to embodiments of the present invention can be used in a wide variety of applications such as a switcher for telecommunications; personal digital assistant (PDA) or the like; and a personal computer (PC), a router, or a hub for basic input/output system (BIOS)/networking as understood by one skilled in the art. The semiconductor devices also can be included in a mass storage device such as a memory card, a universal serial bus (USB) drive, a digital camera, and a voice/audio recorder as understood by one skilled in the art.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

Various operations will be described as multiple discrete steps performed in a manner that is most helpful in understanding the invention. However, the order in which the steps are described does not imply that the operations are order-dependent or that the order that steps are performed must be the order in which the steps are presented.

Further, well-known structures and devices are not shown in order not to obscure the description of the invention with unnecessary detail.

While the present invention has been particularly shown and described with reference to the exemplary embodiments thereof, it will be understood by those skilled in the art that the foregoing and other changes in form and details may be made therein without departing from the spirit and scope of the present invention.

What is claimed is:

1. A semiconductor device comprising:
an insulation structure over a substrate, the insulation structure having an opening defined therethrough;
a first layer pattern formed on sidewalls and a bottom of the opening; and
a second layer pattern comprising a phase change material overlying the first layer pattern and substantially filling the opening.

2. The device of claim 1, wherein the second layer pattern has an upper surface substantially co-planar with a top surface of the insulation structure.

3. The device of claim 1, wherein the first layer pattern comprises a transition metal oxide.

4. The device of claim 5, wherein the transition metal oxide comprises at least one of titanium oxide, niobium oxide and zirconium oxide.

5. The device of claim 1, wherein the opening has an aspect ratio from about 5 to about 8.

6. The device of claim 1, wherein the opening has a width of about 50 nm and a height of about 3000 Å.

7. The device of claim 1, wherein the first layer pattern comprises a material having an electrical resistance of about 1×10⁶Ω to about 1×10⁹Ω.

8. The device of claim 1, wherein the first layer pattern has a thickness of about 10 Å to about 30 Å.

9. The device of claim 1, wherein the first layer pattern is amorphous.

10. The device of claim 1, wherein the first layer pattern has a substantially uniform thickness.

11. The device of claim 1, wherein the second layer pattern has crystal structure comprises a mixture of FCC and HCP crystal structures.

12. The device of claim 1, further comprising an electrode on the first layer pattern.

13. The device of claim 12, wherein the electrode directly contacts the top surface of the insulation structure.

14. A phase change memory device comprising:
a component on a substrate, the component comprising at least one of a conductive material and a semiconductor material;
an insulation structure over the substrate, the insulation structure having an opening defined therein, wherein the component is exposed by the opening;
a nucleation layer pattern on sidewalls of the opening and on the component; and
a phase change material layer pattern on the nucleation layer pattern, the phase change material layer pattern substantially filling the opening.

15. The device of claim 14, wherein the phase change material layer pattern has an upper surface substantially co-planar with a top surface of the insulation structure; and
an electrode over the phase change material layer pattern.

16. The device of claim 14, wherein the component comprises a lower electrode.

17. The device of claim 14, wherein the component comprises a diode and a lower electrode, which are sequentially stacked.

18. A method of forming a phase change memory device, the method comprising:
forming an insulation structure over a substrate, the insulation structure having an opening defined therethrough;
forming a first layer pattern on sidewalls and a bottom of the opening; and
forming a second layer pattern on the first layer pattern and substantially filling the opening, the second layer pattern comprising phase change material.

19. The method of claim 18, wherein the second layer has an upper surface substantially co-planar with a top surface of the insulation structure.

20. The method of claim 18, wherein the first layer pattern comprises a transition metal oxide.

21. The method of claim 20, wherein the transition metal oxide comprises at least one of titanium oxide, niobium oxide and zirconium oxide.

22. The method of claim 18, wherein the first layer pattern comprises a material having an electrical resistance of about 1×10⁶Ω to about 1×10⁹Ω.

23. The method of claim 18, wherein the first layer pattern is amorphous.

24. The method of claim 18, wherein the first layer pattern has a substantially uniform thickness.

25. The method of claim 18, wherein the second layer pattern has crystalline structure comprising a mixture of FCC and HCP crystal structures.

26. The method of claim 25, wherein the electrode directly contacts the top surface of the insulation structure.

27. The method of claim 18, further comprising a component comprising at least one of a conductive material and a semiconductor material, wherein the first layer pattern contacts the component.

28. A method of forming a phase change memory device, the method comprising:
forming a component on a substrate, the component comprising at least one of a conductive material and a semiconductor material;
forming an insulation structure over the substrate, the insulation structure having an opening defined therein, wherein the component is exposed by the opening;
forming a nucleation layer pattern on sidewalls of the opening and on the component; and
forming a phase change material layer pattern on the nucleation layer pattern, the phase change material layer pattern substantially filling the opening.

29. The method of claim 28, wherein the phase change material layer pattern has an upper surface substantially co-planar with a top surface of the insulation structure; and
an electrode over the phase change material layer pattern.

30. The method of claim 28, wherein the component comprises a lower electrode.

31. The method of claim 28, wherein the component comprises a diode and a lower electrode, which are sequentially stacked.

32. A method of forming a phase change memory device, the method comprising:
providing a semiconductor substrate having a component formed thereon, the component comprising at least one of a conductive material and a semiconductor material;
forming an insulation structure over the substrate, the insulation structure having an opening defined therein to expose at least a portion of the component;
forming a nucleation layer on a top surface of the insulating structure and on sidewalls of the opening, and on the component using an ALD process; and
forming a phase change material layer on the nucleation layer pattern, the phase change material layer filling the opening.

33. The method of claim 32, further comprising planarizing the resulting structure until the top surface of the insulating structure is exposed, thereby form a phase change material pattern substantially filling the opening.

34. The method of claim 32, further comprising planarizing the resulting structure until a top surface of the nucleation layer pattern is exposed, thereby form a phase change material pattern substantially filling the opening.

35. The method of claim 28, wherein forming the second layer pattern comprises forming a second layer using at least one of CVD, ALD, CVD, metal-organic CVD (MOCVD), physical vapor deposition (PVD) over the first layer overlying the insulating structure and within the opening.

36. A method of forming a phase change memory device, the method comprising:
forming an insulation structure on a semiconductor substrate, the insulation structure having an opening to expose a region of the substrate;
partially filling the opening with an epitaxial pattern within the opening;
performing an ion implantation process on the epitaxial pattern to form a diode;
forming a lower electrode over the diode;
forming a nucleation layer pattern on sidewalls of the opening and on the lower electrode overlying the diode; and
forming a phase change material layer pattern on the nucleation layer pattern, the phase change material layer pattern substantially filling the opening.

37. The method of claim 37, wherein forming the epitaxial pattern comprises a solid-phase epitaxial growth technique.

38. The method of claim 37, wherein partially filling the opening comprises etching back the epitaxial pattern.

39. The method of claim 37, wherein the phase change material layer pattern has an upper surface substantially co-planar with a top surface of the insulation layer pattern.
